(19) United States
(12) Patent Application Publication
(10) Pub. No.: US 2024/0321714 A1
(43) Pub. Date: Sep. 26, 2024

(54) SEMICONDUCTOR DEVICE AND WIRING SUBSTRATE

(71) Applicant: SHINKO ELECTRIC INDUSTRIES CO., LTD., Nagano (JP)

(72) Inventors: Shinichiro SEKIJIMA, Nagano (JP); Misaki HOSAKA, Nagano (JP)

(21) Appl. No.: 18/609,553

(22) Filed: Mar. 19, 2024

(30) Foreign Application Priority Data
Mar. 22, 2023 (JP) 2023-045152

(51) Int. Cl. H01L 23/498; H01L 23/00

(52) U.S. Cl. CPC H01L 23/49838; H01L 24/13; H01L 24/16; H01L 24/32; H01L 24/73; H01L 2224/13082; H01L 2224/13111; H01L 2224/13139; H01L 2224/13147; H01L 2224/16227; H01L 2224/32225; H01L 2224/73204; H01L 2924/014

(57) ABSTRACT

A semiconductor device includes a wiring substrate, a semiconductor chip including conductive pillars, and a conductive bonding material. The wiring substrate includes electrode pads and via lands electrically connected to each other at a surface of the wiring substrate. A through hole and a cut continuous with the through hole are formed in each electrode pad. In a plan view perpendicular to the surface, the cut of a first electrode pad extends toward a space between a second electrode pad and a third electrode pad adjacent to each other and adjacent to the first electrode pad, a first via land and a second via land adjacent to each other and adjacent to the first electrode pad, or a fourth electrode pad and a third via land adjacent to each other and adjacent to the first electrode pad. The conductive bonding material bonds the electrode pads and the conductive pillars.

### CROSS-REFERENCE TO RELATED APPLICATION

This application is based upon and claims priority to Japanese Patent Application No. 2023-045152, filed on Mar. 22, 2023, the entire contents of which are incorporated herein by reference.

### FIELD

A certain aspect of the embodiment discussed herein is related to semiconductor devices and wiring substrates.

### BACKGROUND

A semiconductor device having a wiring substrate and a semiconductor chip with conductive pillars mounted on the wiring substrate by flip-chip bonding is known (see Japanese Laid-open Patent Publication No. 2020-149991).

### SUMMARY

According to an aspect, a semiconductor device includes a wiring substrate, a semiconductor chip, and a conductive bonding material. The semiconductor device includes electrode pads and via lands at a surface of the wiring substrate. The electrode pads and the via lands are formed in the same plane and electrically connected to each other. A through hole and a cut continuous with the through hole are formed in each electrode pad. In a plan view perpendicular to the surface of the wiring substrate, the cut of a first electrode pad among the electrode pads extends toward a space between (a) a second electrode pad and a third electrode pad that are adjacent to each other and adjacent to the first electrode pad among the electrode pads, (b) a first via land and a second via land that are adjacent to each other and adjacent to the first electrode pad among the via lands, or (c) a fourth electrode pad and a third via land that are adjacent to each other and adjacent to the first electrode pad among the electrode pads and the via lands. The semiconductor chip includes conductive pillars and is mounted on the wiring substrate with the conductive pillars facing the wiring substrate. The conductive bonding material bonds the electrode pads and the conductive pillars. The conductive bonding material is partly within the through hole or the through hole and the cut of each electrode pad.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a plan view of a wiring substrate of a semiconductor device according to an embodiment;

FIG. 2 is a sectional view of the semiconductor device according to the embodiment;

FIGS. 3A and 3B are sectional views illustrating a method of manufacturing a semiconductor device according to the embodiment;

FIG. 4 is a sectional view of part of a semiconductor device according to a reference example; and

FIGS. 5A and 5B are diagrams illustrating variations of an arrangement of electrode pads and via lands according to the embodiment.

### DESCRIPTION OF EMBODIMENT

In recent years, there has been an increasing demand for low-profile semiconductor devices. In order to reduce the thickness of a semiconductor device, the distance between a wiring substrate and a semiconductor chip may be reduced. Using low conductive pillars, however, may cause a conductive bonding material used to connect the wiring substrate and the semiconductor chip, such as solder, to spread along the side surfaces of the conductive pillars and the surface of the semiconductor chip, resulting in a short circuit due to contact between portions of the conductive bonding material.

According to an embodiment of the present disclosure, it is possible to reduce the thickness of a semiconductor device and a wiring substrate while controlling a short circuit.

According to an aspect of the present disclosure, a semiconductor device and a wiring substrate that are reduced in thickness while controlling a short circuit are provided.

One or more embodiments are described below with reference to the accompanying drawings. In the following description and the drawings, the same constituent elements having substantially the same functional configuration may be referred to using the same reference numeral, and a duplicate description thereof may be omitted. Furthermore, according to the present disclosure, a Cartesian coordinate system for a three-dimensional space consisting of an X-axis line, a Y-axis line, and a Z-axis line that are orthogonal to one another is employed to describe the position and the configuration of an object such as a constituent element, with the origin being at the center of the constituent element. X1 and X2 represent opposite directions along the X-axis line, which directions may be collectively referred to as “X1-X2 direction.” Y1 and Y2 represent opposite directions along the Y-axis line, which directions may be collectively referred to as “Y1-Y2 direction.” Z1 and Z2 represent opposite directions along the Z-axis line, which directions may be collectively referred to as “Z1-Z2 direction.” A plane including the X1-X2 direction and the Y1-Y2 direction is referred to as “XY plane.” A plane including the Y1-Y2 direction and the Z1-Z2 direction is referred to as “YZ plane.” A plane including the Z1-Z2 direction and the X1-X2 direction is referred to as “ZX plane.” For convenience, the Z1-Z2 direction is defined as vertical directions with the Z1 side being an upper side and the Z2 side being a lower side. Furthermore, a plan view refers to a view of an object from the Z1 side, and a planar shape refers to the shape of an object as viewed from the Z1 side. A semiconductor device and a wiring substrate, however, may be used in an inverted position and may be oriented at any angle.

### [Semiconductor Device Structure]

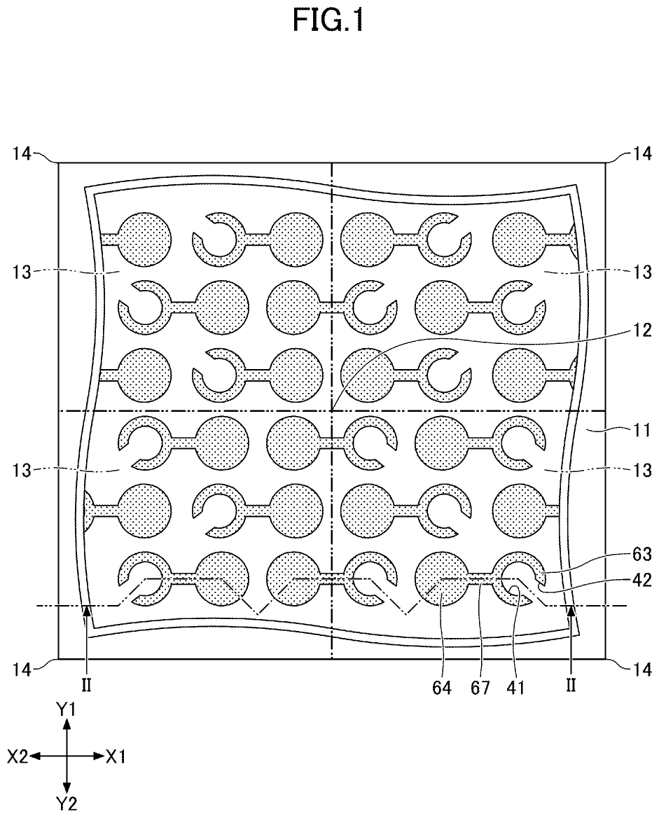

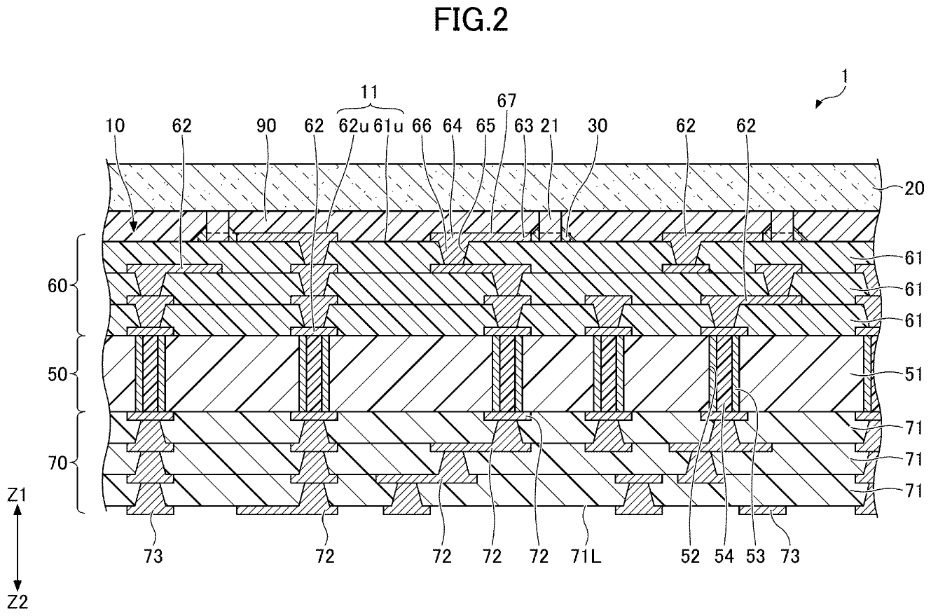

First, a structure of a semiconductor device according to an embodiment is described. FIG. 1 is a plan view of a wiring substrate 10 of a semiconductor device 1 according to the embodiment. FIG. 2 is a sectional view of the semiconductor device 1 according to the embodiment, taken along the line II-II of FIG. 1.

Referring to FIGS. 1 and 2, the semiconductor device 1 includes the wiring substrate 10, a semiconductor chip 20, conductive bonding members 30 (electrically conductive bonding material), and an underfill material 90. The wiring substrate 10 has a surface (upper surface) 11 substantially parallel to the XY plane.

The wiring substrate 10 includes, for example, a core layer 50, a build-up layer 60 on the upper surface of the core layer 50, and a build-up layer 70 on the lower surface of the core layer 50. The wiring substrate 10 may be a coreless substrate without a core layer.

The core layer 50 includes an insulating base 51 in which through holes 52 are formed, through vias 53 formed one on the inner wall surface of each of the through holes 52, and a filling material 54 that fills in the inside of each of the through vias 53. Examples of materials for the core layer 50 include glass epoxy, and examples of materials for the through vias 53 include copper (Cu). The filling material 54 may be omitted, and the through holes 52 may be filled entirely with metal that serves as the through vias 53.

The build-up layer 60 includes insulating layers 61 and wiring layers 62. The wiring layers 62 include electrode pads 63 for connection to the semiconductor chip 20 and via lands 64 on an uppermost surface 61u of the insulating layers 61, namely, an upper surface of the uppermost insulating layer 61. The number of the electrode pads 63 is equal to the number of the via lands 64. The via lands 64 are electrically connected one to each of the electrode pads 63. For example, a conductive pattern 67 may extend between each of the via lands 64 and the corresponding electrode pad 63 to electrically connect the via land 64 and the electrode pad 63 as illustrated in FIGS. 1 and 2. The material of the wiring layers 62 is, for example, an electrical conductor such as copper. The material of the insulating layers 61 is, for example, prepreg.

The electrode pads 63 and the via lands 64 are included in the uppermost wiring layer 62 (the wiring layer 62 most distant from the core layer 50). The via lands 64 are in contact with the other wiring layers 62 closer to the core layer 50 than the uppermost wiring layer 62 through via conductors 66 in via holes 65 formed in the insulating layers 61 between the wiring layers 62. That is, the via lands 64 are formed in the same plane as the electrode pads 63. The planar shape of the via lands 64 is, for example, circular.

The planar shape of the electrode pads 63 is, for example, an arc shape. The planar shape of the electrode pads 63 may also be a broken ring shape or the shape of a ring with a gap, such as the shape of the letter C in the Latin alphabet. Each of the electrode pads 63 has a through hole 41 piercing through the electrode pad 63 and a cut (gap) 42 continuous with (connecting to) the through hole 41. The through hole 41 is, for example, a substantially cylindrical space formed in the center of the electrode pad 63. The cut 42 rectilinearly extends outward of the electrode pad 63 from the through hole 41. The uppermost surface 61u of the insulating layers 61 is exposed through the through hole 41 and the cut 42.

For example, the outside diameter of the electrode pads 63 may be equal to the diameter of the via lands 64. The electrode pads 63 and the via lands 64 may be arranged in a substantially quadrangular lattice in a plan view. The electrode pads 63 and the via lands 64 may also be arranged in a substantially staggered manner in a plan view. Referring to the illustration of FIG. 1, in a plan view, with respect to one or more of the electrode pads 63, the cut 42 extends toward the space between two of the via lands 64 which two are adjacent to each other and adjacent to the electrode pad 63 in which the cut 42 is formed. For example, the cut 42 extends radially outward from the center of the electrode pad 63 to face the space between adjacent two of the via lands 64 adjacent to the electrode pad 63 in a plan view.

For example, the surface 11 of the wiring substrate 10, which includes the upper surface of the uppermost insulating layer 61 (the uppermost surface 61u) and an upper surface 62u of the uppermost wiring layer 62, has a rectangular planar shape, and has four rectangular regions 13. Each of the rectangular regions 13 has four sides that are parallel to the four sides of the surface 11. The planar shapes of the four rectangular regions 13 are congruent. The surface 11 is constituted of the four rectangular regions 13. That is, the rectangular regions 13 are obtained by quadrisecting the surface 11 (into four equal regions). In each of the four rectangular regions 13, the cuts 42 of the electrode pads 63 extend parallel to a line segment that connects a center 12 of the surface 11 and one of four vertices 14 of the surface 11 which one is included in the rectangular region 13. From another point of view, the cuts 42 radially extend relative to the center 12 of the surface 11. Furthermore, the cuts 42 extend outward relative to the center as viewed from the center 12 of the surface 11.

The build-up layer 70 includes insulating layers 71 and wiring layers 72. The wiring layers 72 include electrode pads 73 for connection to an external device on a lowermost surface 71L of the insulating layers 71. The material of the wiring layers 72 is, for example, an electrical conductor such as copper. The material of the insulating layers 71 is, for example, prepreg. Solder balls may be provided on the electrode pads 73.

The electrode pads 63 and the electrode pads 73 are electrically connected to each other via the wiring layers 62, the through vias 53, and the wiring layers 72. The number of the insulating layers 61 and the wiring layers 62 included in the build-up layer 60 and the number of the insulating layers 71 and the wiring layers 72 included in the build-up layer 70 are not limited in particular.

The semiconductor chip 20 includes (electrically) conductive pillars 21. The number of the conductive pillars 21 is equal to the number of the electrode pads 63. The material of the conductive pillars 21 is, for example, an electrical conductor such as copper. The semiconductor chip 20 is mounted on the surface 11 of the wiring substrate 10 by flip-chip bonding. The diameter of the conductive pillars 21 is smaller than the inside diameter of the through holes 41. Each of the conductive pillars 21 is partly inside the through hole 41. The underfill material 90 fills in the space between the semiconductor chip 20 and the wiring substrate 10.

The number of the conductive bonding members 30 is equal to the number of the electrode pads 63 and the number of the conductive pillars 21. The conductive bonding members 30 are joined one to each of the electrode pads 63 and each of the conductive pillars 21. The electrode pads 63 and the conductive pillars 21 are electrically connected by the conductive bonding members 30. Each of the conductive bonding members 30 is partly within the region of the through hole 41. The region of the through hole 41 may include the cut 42. The through hole 41 may be filled with the conductive pillar 21 and the conductive bonding member 30. The cut 42 may be filled with the conductive bonding member 30. The cut 42 may include an area that is not filled with the conductive bonding member 30. Examples of materials for the conductive bonding members 30 include lead-free (Pb-free) solders such as tin (Sn) solders, tin-silver (Sn—Ag) solders, tin-copper (Sn—Cu) solders, and tin-silver-copper (Sn—Ag—Cu) solders.

### [Semiconductor Device Manufacturing Method]

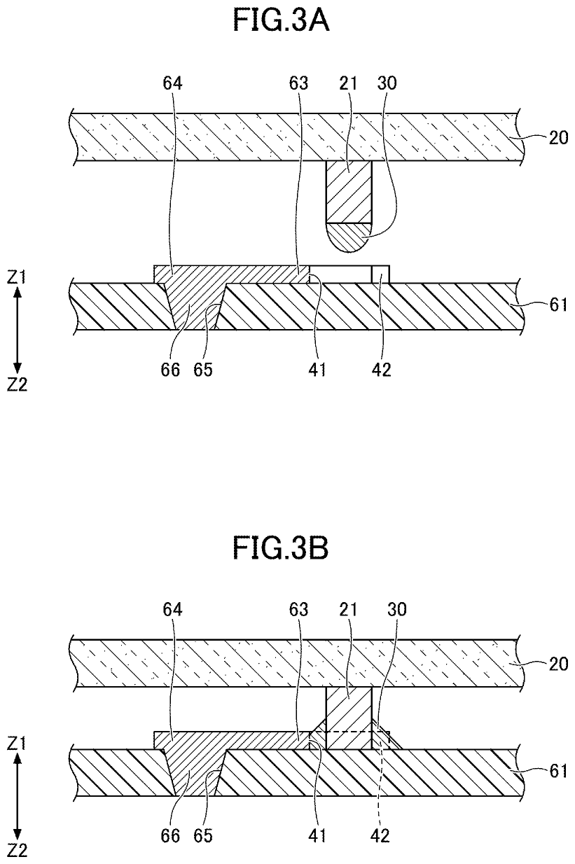

Next, a method of manufacturing a semiconductor device according to the embodiment is described. FIGS. 3A and 3B are sectional views for illustrating a method of manufacturing a semiconductor device according to the embodiment. FIGS. 3A and 3B are enlarged views of one set of the electrode pad 63, the via land 64, the conductive pillar 21, and the conductive bonding member 30 and its periphery.

First, as illustrated in FIG. 3A, the wiring substrate 10 and the semiconductor chip 20 are prepared.

The wiring layers 62 and 72 included in the wiring substrate 10 may be formed by, for example, a semi-additive process or a subtractive process. For example, to form the wiring layer 62 including the electrode pads 63 and the via lands 64, first, a plating seed layer is formed. Next, a mask to expose a region in which the wiring layer 62 is to be formed is formed on the plating seed layer. Then, electroplating using the plating seed layer as a power supply channel is performed. Thereafter, the mask is removed, and then, part of the plating seed layer covered by the mask is removed. The wiring layer 62 including the electrode pads 63 and the via lands 64 may thus be formed.

To prepare the semiconductor chip 20, the conductive bonding members 30 are formed on the surfaces of the conductive pillars 21 that face the wiring substrate 10, using plating.

After the wiring substrate 10 and the semiconductor chip 20 are prepared, a flux is applied to the surfaces of the conductive bonding members 30. Next, reflow soldering is performed with the semiconductor chip 20 being placed on the wiring substrate 10. As a result, the conductive bonding members 30 melt and thereafter solidify to bond the electrode pads 63 and the conductive pillars 21 to each other as illustrated in FIG. 3B.

Thereafter, the space between the wiring substrate 10 and the semiconductor chip 20 is filled with the underfill material 90 (see FIG. 2).

The semiconductor device 1 according to the embodiment may thus be manufactured.

According to the semiconductor device 1 of this embodiment, the through holes 41 are formed one in each of the electrode pads 63, and each of the conductive pillars 21 is partly inside the through hole 41. Therefore, it is possible to reduce the distance between the wiring substrate 10 and the semiconductor chip 20 without reducing the height of the conductive pillars 21.

Furthermore, the cuts 42 are formed one in each of the electrode pads 63. Therefore, the molten conductive bonding members 30 are more likely to flow along the surface 11 than flow along the side surfaces of the conductive pillars 21 toward the semiconductor chip 20. Accordingly, it is possible to reduce or prevent short circuits due to the flow of the conductive bonding members 30 on a surface of the semiconductor chip 20.

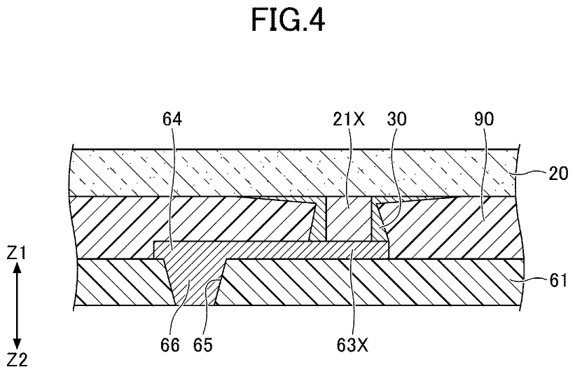

Here, a reference example is described. The reference example is different from the embodiment mainly in conductive pillars and the shape of electrode pads. FIG. 4 is an enlarged sectional view of part of a semiconductor device according to the reference example, illustrating a set of an electrode pad, a via land, a conductive pillar and a conductive bonding member and its periphery.

According to the semiconductor device of the reference example, the wiring substrate 10 includes electrode pads 63X in place of the electrode pads 63, and the semiconductor chip 20 includes conductive pillars 21X in place of the conductive pillars 21.

The material and the thickness of the electrode pads 63X are equal to the material and the thickness of the electrode pads 63. The planar shape of the electrode pads 63X is circular. Neither a through hole nor a cut is formed in the electrode pads 63X. The conductive pillars 21X are lower (shorter) than the conductive pillars 21 by the thickness of the electrode pads 63X. Otherwise, the configuration of the reference example may be equal to the configuration of the embodiment.

The distance between the wiring substrate 10 and the semiconductor chip 20 according to the reference example is equal to the distance between the wiring substrate 10 and the semiconductor chip 20 according to the embodiment. Accordingly, the reference example can also reduce thickness. No through holes or cuts, however, are formed in the electrode pads 63X. Therefore, as illustrated in FIG. 4, the molten conductive bonding members 30 are likely to flow toward the semiconductor chip 20 along the side surfaces of the conductive pillars 21X to reach a surface of the semiconductor chip 20 that faces the wiring substrate 10. Furthermore, the molten conductive bonding members 30 may reach the surface of the semiconductor chip 20 facing the wiring substrate 10 to spread over this surface as well. This may cause a short circuit due to contact between the conductive bonding members 30.

In contrast, according to this embodiment, as described above, the molten conductive bonding members 30 are less likely to flow along the side surfaces of the conductive pillars 21 toward the semiconductor chip 20, so that it is possible to reduce or prevent short circuits due to the flow of the conductive bonding members 30 on the surface of the semiconductor chip 20.

Furthermore, in a plan view, with respect to one or more of the electrode pads 63, the cut 42 extends toward the space between two of the via lands 64 which two are adjacent to each other and adjacent to the electrode pad 63 in which the cut 42 is formed. Therefore, it is possible to reduce or prevent contact between the conductive bonding members 30 flowing in the electrode pads 63, and accordingly, to reduce or prevent short circuits due to contact between the conductive bonding members 30.

Specifically, because the cuts 42 radially extend relative to the center 12 of the surface 11, a short circuit due to contact between the flowing conductive bonding members 30 is easily controllable. Furthermore, the amount of thermal expansion of the electrode pads 63 is smaller in directions in which the cuts 42 extend than in other directions. Therefore, it is possible to reduce the amount of thermal expansion of the electrode pads 63 in radial directions relative to the center 12. The semiconductor chip 20 has a lower coefficient of thermal expansion than the metal material of the electrode pads 63. Therefore, it is possible to reduce the difference between the amount of thermal expansion of the semiconductor chip 20 and the amount of thermal expansion of the electrode pads 63 in directions in which the cuts 42 extend. Furthermore, regarding an aggregate of the electrode pads 63 as a single object, in a plan view, directions in which the conductive bonding members 30 flow and directions in which the object is likely to expand are low in anisotropy. Therefore, it is easy to control the unevenness of thermal stress and to reduce or prevent breakage due to excessive concentration of thermal stress, for example.

All examples and conditional language provided herein are intended for pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

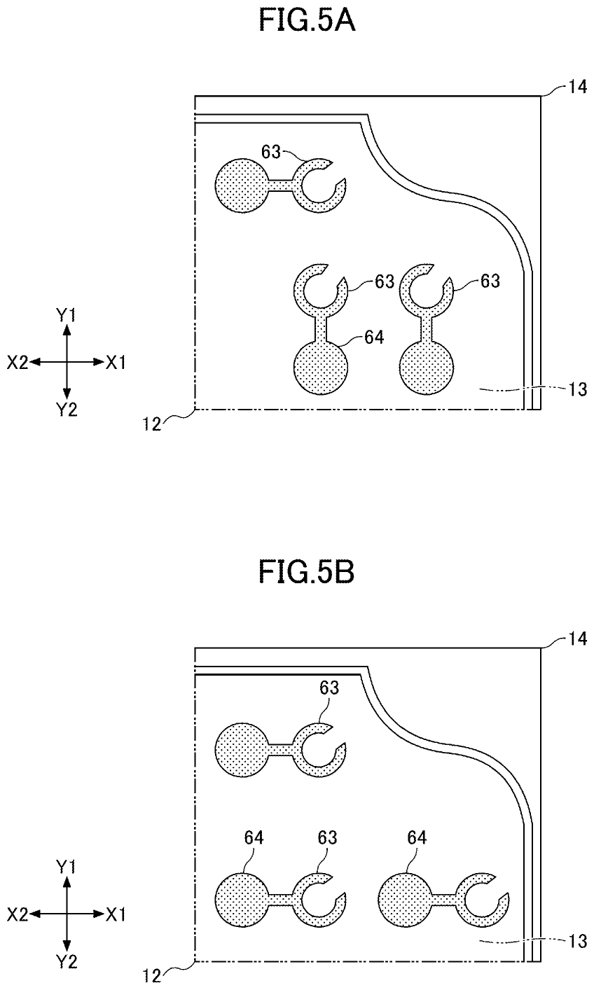

For example, in a plan view, with respect to one or more of the electrode pads 63, the cut 42 may extend toward the space between two of the electrode pads 63 which two are adjacent to each other and adjacent to the electrode pad 63 in which the cut 42 is formed as illustrated in FIG. 5A, or may extend toward the space between one of the electrode pads 63 and one of the via lands 64 which ones are adjacent to each other and adjacent to the electrode pad 63 in which the cut 42 is formed as illustrated in FIG. 5B. In each case, the same effects as in the case where the cut 42 extends toward the space between two of the via lands 64 which two are adjacent to each other and adjacent to the electrode pad 63 in which the cut 42 is formed can be achieved.

What is claimed is:

1. A semiconductor device comprising:
a wiring substrate including a plurality of electrode pads and a plurality of via lands at a surface of the wiring substrate, the electrode pads and the via lands being formed in a same plane and electrically connected to each other, wherein
a through hole and a cut continuous with the through hole are formed in each of the electrode pads, and
in a plan view perpendicular to the surface of the wiring substrate, the cut of a first electrode pad among the electrode pads extends toward a space between
(a) a second electrode pad and a third electrode pad that are adjacent to each other and adjacent to the first electrode pad among the electrode pads,
(b) a first via land and a second via land that are adjacent to each other and adjacent to the first electrode pad among the via lands, or
(c) a fourth electrode pad and a third via land that are adjacent to each other and adjacent to the first electrode pad among the electrode pads and the via lands;
a semiconductor chip including a plurality of conductive pillars and mounted on the wiring substrate with the conductive pillars facing the wiring substrate; and
a conductive bonding material bonding the electrode pads and the conductive pillars, the conductive bonding material being partly within the through hole or the through hole and the cut of each of the electrode pads.

2. The semiconductor device as claimed in claim 1, wherein a diameter of a conductive pillar among the conductive pillars is smaller than an inside diameter of the through hole of an electrode pad among the electrode pads, the electrode pad being bonded to the conductive pillar by the conductive bonding material.

3. The semiconductor device as claimed in claim 1, wherein the cut of each of the electrode pads extends outward of the through hole of said each of the electrode pads as seen from a center of the surface of the wiring substrate.

4. The semiconductor device as claimed in claim 1, wherein the cuts of the electrode pads radially extend relative to a center of the surface of the wiring substrate.

5. The semiconductor device as claimed in claim 1, wherein
the surface of the wiring substrate has a planar shape of a rectangle, and
in each of four rectangular regions into which the rectangle is quadrisected, each of the four rectangular regions having four sides that are parallel to four sides of the rectangle, the cuts of the electrode pads extend parallel to a line segment that connects a center of the surface of the wiring substrate and one of four vertices of the rectangle which one is included in said each of the four rectangular regions.

6. The semiconductor device as claimed in claim 1, wherein a number of the electrode pads is equal to a number of the via lands.

7. The semiconductor device as claimed in claim 1, wherein the wiring substrate further includes a plurality of other electrode pads at another surface on an opposite side from the surface at which the electrode pads and the via lands are formed, said other electrode pads being electrically connected to the electrode pads at the surface.

8. The semiconductor device as claimed in claim 1, wherein the via lands have a circular planar shape.

9. The semiconductor device as claimed in claim 1, wherein the electrode pads and the via lands are arranged in a quadrangular lattice or in a staggered manner in the plan view.

10. The semiconductor device as claimed in claim 1, wherein the wiring substrate further includes a plurality of conductive patterns at the surface of the wiring substrate, the conductive patterns extending one between each of the electrode pads and each of the via lands to electrically connect said each of the electrode pads and said each of the via lands.

11. The semiconductor device as claimed in claim 1, wherein each of the conductive pillars is partly inside the through hole of each of the electrode pads.

12. A wiring substrate comprising:
a plurality of electrode pads and a plurality of via lands at a surface of the wiring substrate, the electrode pads and the via lands being formed in a same plane and electrically connected to each other,
wherein a through hole and a cut continuous with the through hole are formed in each of the electrode pads, and
in a plan view perpendicular to the surface of the wiring substrate, the cut of a first electrode pad among the electrode pads extends toward a space between
(a) a second electrode pad and a third electrode pad that are adjacent to each other and adjacent to the first electrode pad among the electrode pads,
(b) a first via land and a second via land that are adjacent to each other and adjacent to the first electrode pad among the via lands, or
(c) a fourth electrode pad and a third via land that are adjacent to each other and adjacent to the first electrode pad among the electrode pads and the via lands.

13. The wiring substrate as claimed in claim 12, wherein the cut of each of the electrode pads extends outward of the through hole of said each of the electrode pads as seen from a center of the surface of the wiring substrate.

14. The wiring substrate as claimed in claim 12, wherein the cuts of the electrode pads radially extend relative to a center of the surface of the wiring substrate.

15. The wiring substrate as claimed in claim 12, wherein
the surface of the wiring substrate has a planar shape of a rectangle, and
in each of four rectangular regions into which the rectangle is quadrisected, each of the four rectangular regions having four sides that are parallel to four sides of the rectangle, the cuts of the electrode pads extend parallel to a line segment that connects a center of the surface of the wiring substrate and one of four vertices of the rectangle which one is included in said each of the four rectangular regions.

16. The wiring substrate as claimed in claim 12, wherein a number of the electrode pads is equal to a number of the via lands.

17. The wiring substrate as claimed in claim 12, further comprising:
a plurality of other electrode pads at another surface on an opposite side from the surface at which the electrode pads and the via lands are formed, said other electrode pads being electrically connected to the electrode pads at the surface.

18. The wiring substrate as claimed in claim 12, wherein the via lands have a circular planar shape.

19. The wiring substrate as claimed in claim 12, wherein the electrode pads and the via lands are arranged in a quadrangular lattice or in a staggered manner in the plan view.

20. The wiring substrate as claimed in claim 12, further comprising:
a plurality of conductive patterns at the surface of the wiring substrate, the conductive patterns extending one between each of the electrode pads and each of the via lands to electrically connect said each of the electrode pads and said each of the via lands.
